(19) United States
(12) Patent Application Publication
(10) Pub. No.: US 2025/0248081 A1
(43) Pub. Date: Jul. 31, 2025

(54) SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Naoki MITAMURA, Matsumoto-city (JP); Yuki SAWA, Matsumoto-city (JP); Takayuki KOBAYASHI, Matsumoto-city (JP)

(21) Appl. No.: 19/087,560

(22) Filed: Mar. 23, 2025

Related U.S. Application Data
(63) Continuation of application No. PCT/JP2024/009413, filed on Mar. 11, 2024.

(30) Foreign Application Priority Data
Apr. 14, 2023 (JP) 2023-066754

(51) Int. Cl. H10D 62/10; H10D 12/00; H10D 64/64; H10D 84/00

(52) U.S. Cl. CPC H10D 62/107; H10D 84/161; H10D 12/481; H10D 64/64

(57) ABSTRACT

A semiconductor device including a transistor portion and a diode portion, including a plurality of trench portions provided at a front surface of a semiconductor substrate, a drift region of a first conductivity type provided in the semiconductor substrate, a base region of a second conductivity type provided above the drift region, an emitter region of the first conductivity type provided above the base region and having a doping concentration higher than that of the drift region, a contact region of the second conductivity type provided above the base region with a doping concentration higher than the base region, an injection suppression region provided at the front surface of the semiconductor substrate, and an emitter electrode provided above the semiconductor substrate, in which the transistor portion has a main region for performing transistor operation, and the injection suppression region is provided in the main region of the transistor portion.

The contents of the following patent application(s) are incorporated herein by reference:
NO. 2023-066754 filed in JP on Apr. 14, 2023.
NO. PCT/JP2024/009413 filed in WO on Mar. 11, 2024.

### BACKGROUND

### 1. Technical Field

The present invention relates to a semiconductor device.

### 2. Related Art

Patent document 1 describes “in a semiconductor device including a switching device and a diode, suppressing reduction of withstand capability of the switching device while reducing recovery loss during diode operation.

### PRIOR ART DOCUMENTS

### Patent Documents

Patent Document 1: Japanese Patent No. 7101593
Patent Document 2: Japanese Patent Application Publication No. 2022-59429
Patent Document 3: Japanese Patent No. 5919121

### BRIEF DESCRIPTION OF THE DRAWINGS

FIG. 1A illustrates an example of a top view of a semiconductor device 100.

FIG. 1B illustrates an example of a cross section a-a′ in FIG. 1A.

FIG. 1C illustrates an example of a cross section b-b′ in FIG. 1A.

FIG. 1D illustrates the cross section b-b′ of a modification example of the semiconductor device 100.

FIG. 2A illustrates the cross section b-b′ of a modification example of the semiconductor device 100.

FIG. 2B illustrates the cross section b-b′ of a modification example of the semiconductor device 100.

FIG. 2C illustrates the cross section b-b′ of a modification example of the semiconductor device 100.

FIG. 2D illustrates the cross section b-b′ of a modification example of the semiconductor device 100.

FIG. 2E illustrates the cross section b-b′ of a modification example of the semiconductor device 100.

FIG. 3A illustrates an example of a top view of a modification example of the semiconductor device 100.

FIG. 3B illustrates an example of a top view of a modification example of the semiconductor device 100.

FIG. 3C illustrates an example of a top view of a modification example of the semiconductor device 100.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a particular direction. For example, the Z axis is not limited to indicate a height direction with respect to the ground. It is to be noted that a +Z axis direction and a −Z axis direction are directions opposite to each other. If the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis direction and the Y axis direction.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to an acceptor concentration set as a negative ion concentration, taking into account polarities of electric charges. As an example, when the donor concentration is ND and the acceptor concentration is NA, the net doping concentration at any position is given as ND-NA. In the present specification, the net doping concentration may be simply described as the doping concentration.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type.

When a concentration distribution of the donor, acceptor, or net doping has a peak in a region, a value of the peak may be defined as the concentration of the donor, acceptor, or net doping in the region. In a case where the concentration of the donor, acceptor, or net doping is approximately uniform in a region, or the like, an average value of the concentration of the donor, acceptor, or net doping in the region may be defined as the concentration of the donor, acceptor, or net doping.

Each embodiment shows an example in which a first conductivity type is set as an N type, and a second conductivity type is set as a P type; however, the first conductivity type may be the P type, and the second conductivity type may be the N type. In this case, conductivity types of a substrate, layer, region, and the like in each embodiment each have opposite polarities.

The present specification employs the S unit system. In the present specification, a unit of a distance or length may be represented by cm (centimeter). In this case, various calculations may be converted into m (meter) to be calculated. As for numeric representation of power of 10, for example, the representation 1E+16 indicates 1×10¹⁶, and the representation 1E−16 indicates 1×10⁻¹⁶.

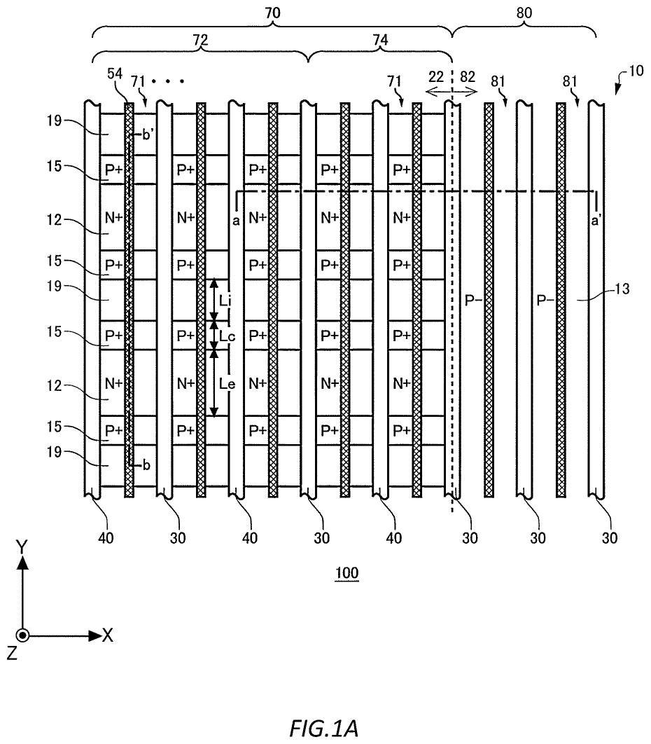

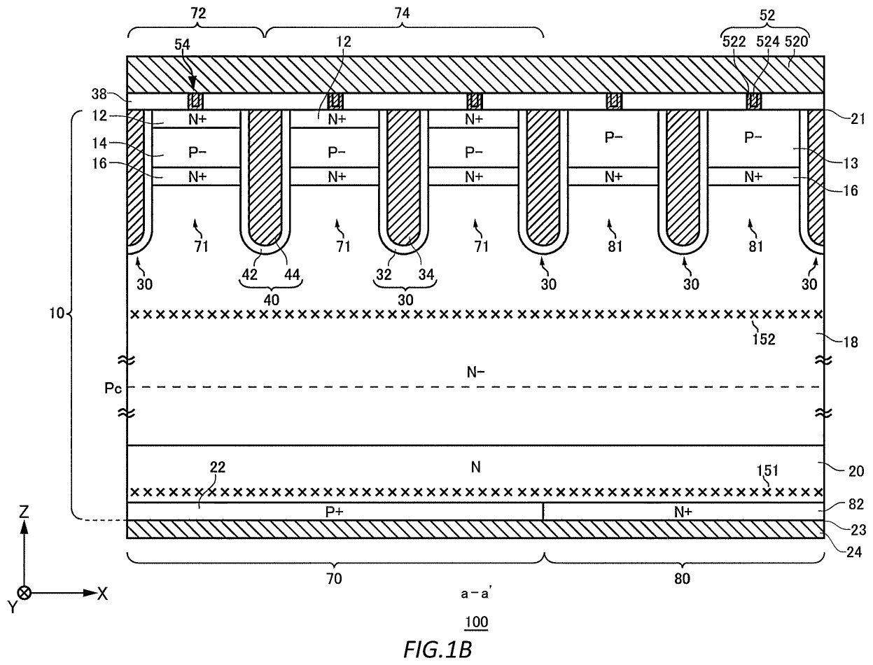

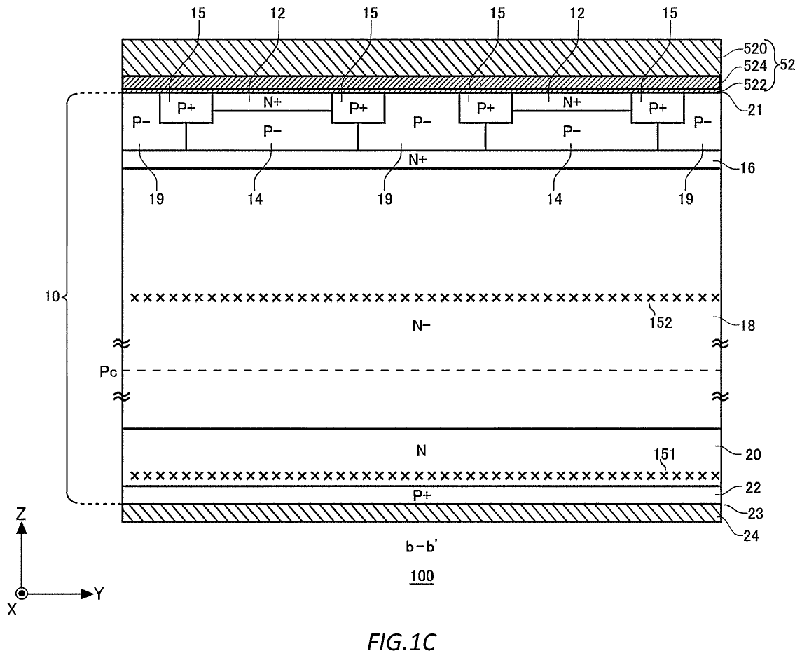

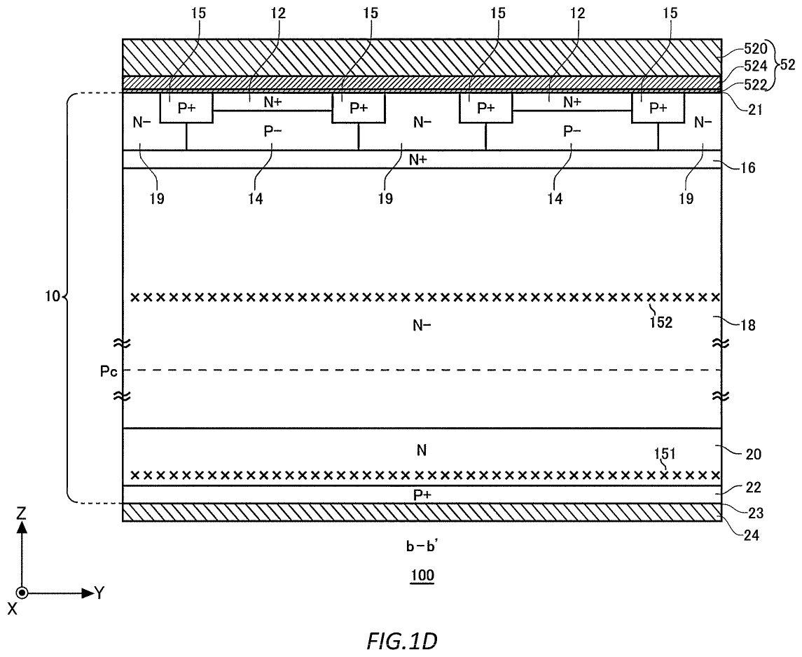

FIG. 1A illustrates an example of a top view of a semiconductor device 100. The semiconductor device 100 in the present example is a semiconductor chip including a transistor portion 70 and a diode portion 80.

The semiconductor substrate 10 is a substrate which is formed of a semiconductor material. The semiconductor substrate 10 may be a silicon substrate or may be a silicon carbide substrate. The semiconductor substrate 10 in the present example is the silicon substrate. It is to be noted that when simply referred to as a top view in the present specification, it means that an upper surface side of the semiconductor substrate 10 is viewed from above. As will be described below, the semiconductor substrate 10 includes a front surface 21 and a back surface 23.

The transistor portion 70 is a region obtained by projecting a collector region 22 provided at the back surface 23 side of the semiconductor substrate 10 onto the upper surface of the semiconductor substrate 10. The collector region 22 will be described below. The transistor portion 70 may include a transistor such as an IGBT. In the present example, the transistor portion 70 is an IGBT. It is to be noted that the transistor portion 70 may be another transistor such as a MOSFET.

The diode portion 80 is a region obtained by projecting a cathode region 82 provided at the back surface 23 side of the semiconductor substrate 10 onto the upper surface of the semiconductor substrate 10. The cathode region 82 will be described below. On the back surface 23 of the semiconductor substrate 10, the collector region 22 may be provided in a region other than the cathode region 82. The diode portion 80 may include a diode such as a Free Wheel Diode (FWD) provided in direct contact with the transistor portion 70 at the upper surface of the semiconductor substrate 10.

In the present drawing, regions surrounding an active region of the semiconductor device 100 are illustrated, and other regions are omitted. For example, an edge termination structure portion may be provided in an outer region in the Y axis direction of the semiconductor device 100 in the present example. The edge termination structure portion reduces electric field strength at the upper surface side of the semiconductor substrate 10. The edge termination structure portion has, for example, a guard ring, a field plate, a RESURF, and a structure combining these.

The semiconductor device 100 in the present example includes gate trench portions 40, dummy trench portions 30, emitter regions 12, anode regions 13, contact regions 15, and injection suppression regions 19 at the front surface 21 of the semiconductor substrate 10.

The gate trench portions 40 are an example of a plurality of trench portions provided at the front surface 21 of the semiconductor substrate 10. The gate trench portion may be a trench portion which is electrically connected to a gate metal layer. The gate trench portions 40 are arrayed at predetermined intervals along a predetermined array direction (the X axis direction in the present example). The gate trench portions 40 may be parallel to the front surface 21 of the semiconductor substrate 10 and extend along an extending direction which is perpendicular to the array direction (the Y axis direction in the present example). The gate trench portion 40 may have two extending portions extending along the extending direction and a connecting portion that connects the two extending portions. For example, the gate trench portion 40 has the connecting portion in a region farther outward in the Y axis direction than the illustrated region. When end portions of the two extending portions of the gate trench portion 40 have the connecting portion connecting one another, the electric field strength at the end portions of the extending portions can be reduced.

The dummy trench portions 30 are an example of a plurality of trench portions provided at the front surface 21 of the semiconductor substrate 10. The dummy trench portion 30 may be a trench portion which is electrically connected to an emitter electrode 52. Similar to the gate trench portions 40, the dummy trench portions 30 are arrayed at predetermined intervals along a predetermined array direction (the X axis direction in the present example). The dummy trench portions 30 may be parallel to the front surface 21 of the semiconductor substrate 10 and extend along an extending direction which is perpendicular to the array direction (the Y axis direction in the present example). The dummy trench portion 30 may have two extending portions extending along the extending direction and a connecting portion that connects the two extending portions. For example, the dummy trench portion 30 has the connecting portion in a region farther outward in the Y axis direction than the illustrated region. When end portions of the two extending portions of the dummy trench portion 30 have the connecting portion connecting one another, the electric field strength at the end portions of the extending portions can be reduced.

The transistor portion 70 in the present example has a structure in which the gate trench portions 40 and the dummy trench portions 30 are arrayed repeatedly. That is, the transistor portion 70 in the present example has the gate trench portions 40 and the dummy trench portions 30 at a ratio of 1:1. For example, the transistor portion 70 has the gate trench portions 40 and the dummy trench portions 30 arrayed alternately.

It is to be noted that the ratio between the gate trench portions 40 and the dummy trench portions 30 is not limited to that in the present example. The ratio of the gate trench portions 40 may be greater than the ratio of the dummy trench portions 30, or the ratio of the dummy trench portions 30 may be greater than the ratio of the gate trench portions 40. The ratio between the gate trench portions 40 and the dummy trench portions 30 may be 2:3, or may be 2:4. In addition, the transistor portion 70 may not have the dummy trench portions 30 with all trench portions being the gate trench portions 40.

A contact hole 54 is provided penetrating an interlayer dielectric film 38 described below. The interlayer dielectric film 38 is omitted in FIG. 1A. The contact hole 54 may electrically connect the emitter electrode 52 described below and the semiconductor substrate 10.

In the transistor portion 70, the contact hole 54 is formed above each of the emitter regions 12, the contact regions 15, and the injection suppression regions 19. In the diode portion 80, the contact hole 54 is formed above the anode regions 13. In this manner, one or more contact holes 54 are formed in the interlayer dielectric film 38. The one or more contact holes 54 may be provided extending in the extending direction of the plurality of trench portions.

A mesa portion 71 is a mesa portion provided in direct contact with the trench portions in a plane parallel to the front surface 21 of the semiconductor substrate 10. The mesa portion may be a portion of the semiconductor substrate 10 sandwiched between two adjacent trench portions, and may be a portion from the front surface 21 of the semiconductor substrate 10 to a depth of the lowermost bottom portion of each trench portion.

The mesa portion 71 is provided in direct contact with at least one of the dummy trench portion 30 or the gate trench portion 40 in the transistor portion 70. At the front surface 21 of the semiconductor substrate 10, the mesa portion 71 has the emitter regions 12, the contact regions 15, and the injection suppression regions 19. In the mesa portion 71, the injection suppression region 19, the contact region 15, the emitter region 12, and the contact region 15 are provided repeatedly in this order in the extending direction of the plurality of trench portions. It is to be noted that there may be a region in which the injection suppression region 19 is not provided in between the adjacent contact regions 15. That is, there may be a region in which the emitter region 12 and the contact region 15 are provided alternately in the extending direction of the plurality of trench portions.

The transistor portion 70 has a main region 72 and a boundary region 74. The main region 72 may be a region that performs transistor operation. The main region 72 may be a region which is 50% or more, 80% or more, 90% or more, or 100% or less of the transistor portion 70. The boundary region 74 may be a region affecting hole injection during diode operation of the semiconductor device 100. Although the boundary region 74 in the present example is illustrated as a region corresponding to two mesa portions 71 adjacent to the diode portion 80, it is not limited to this as long as the boundary region 74 is a region affecting hole injection during diode operation. The boundary region 74 may be a region corresponding to one mesa portion 71 adjacent to the diode portion 80, or may be a region corresponding to three or more mesa portions 71 adjacent to the diode portion 80. In the main region and the boundary region, lengths of the emitter region 12 and the contact region 15 and the ratio of the dummy trench portions 30 and the gate trench portions 40 may be different.

The transistor portion 70 in the present example has the emitter region 12, the contact region 15, and the injection suppression region 19 in both the main region 72 and the boundary region 74. The transistor portion 70 may have the injection suppression region 19 at least in the boundary region 74, and may not have the injection suppression region 19 in the main region 72.

When the transistor portion 70 has the injection suppression region 19 at least in the boundary region 74, hole injection during diode operation of the semiconductor device 100 can be suppressed, and reverse recovery loss Err can be reduced. The hole injection suppression by having the injection suppression region 19 will be described below in detail.

The transistor portion 70 in the present example has the injection suppression region 19 in both the main region 72 and the boundary region 74. When the transistor portion 70 has the injection suppression region 19 in both the main region 72 and the boundary region 74, hole injection during diode operation of the semiconductor device 100 can be more reliably suppressed, and reverse recovery loss Err can be reduced.

In the semiconductor device 100 in the present example, the transistor portion 70 and the diode portion 80 are provided in direct contact with one another. Accordingly, an area of the semiconductor chip can be used effectively compared to when a separate joining portion is provided between the transistor portion 70 and the diode portion 80 to suppress hole injection. For example, the joining portion is a region in which a structure that suppresses hole or electron injection is formed, such as a structure in which there is no emitter region 12 on its front surface and its back surface is a collector region. Further, by not providing the joining portion, the transistor portion 70 and the diode portion 80 can be provided as separate small regions. It is to be noted that to further reduce the reverse recovery loss Err, a separate joining portion may also be provided in the present invention.

A mesa portion 81 is a mesa portion provided in direct contact with the trench portions in a plane parallel to the front surface 21 of the semiconductor substrate 10. In the diode portion 80, the mesa portion 81 is provided in a region sandwiched between adjacent dummy trench portions 30. The mesa portion 81 has the anode region 13 at the front surface 21 of the semiconductor substrate 10.

The emitter region 12 is a region of the first conductivity type that has a higher doping concentration than a drift region 18 described below. The emitter region 12 in the present example is of the N+ type as an example. An example of a dopant of the emitter region 12 includes arsenic (As). The emitter region 12 is provided in contact with the gate trench portion 40 at the front surface 21 of the mesa portion 71. The emitter region 12 may be provided extending from one trench portion to another adjacent trench portion in the array direction of the plurality of trench portions. The emitter region 12 in the present example is provided extending in the X axis direction from one of two trench portions sandwiching the mesa portion 71 to the other. The emitter region 12 is also provided below the contact hole 54.

In addition, the emitter region 12 may be or may not be in contact with the dummy trench portion 30. The emitter region 12 in the present example is in contact with the dummy trench portion 30.

A length Le of the emitter region 12 in the extending direction of the trench portions may be 0.1 μm or more and 3 μm or less. That is, in the present example, the length Le of the emitter region 12 in the Y axis direction may be 0.1 μm or more and 3 μm or less.

The contact region 15 is a region of the second conductivity type that has a higher doping concentration than a base region 14 described below. The contact region 15 in the present example is of the P+ type as an example. The contact region 15 in the present example is provided at the front surface 21 of the mesa portion 71. The contact region 15 may be provided extending from one trench portion to another adjacent trench portion in the array direction of the plurality of trench portions. The contact region 15 in the present example is provided extending in the X axis direction from one of two trench portions sandwiching the mesa portion 71 to the other. The contact region 15 may be or may not be in contact with the gate trench portion 40 or the dummy trench portion 30. The contact region 15 in the present example is in contact with the dummy trench portion 30 and the gate trench portion 40. The contact region 15 is also provided below the contact hole 54.

A length Lc of the contact region 15 in the extending direction of the plurality of trench portions may be shorter than the length Le of the emitter region 12 in the extending direction of the plurality of trench portions. That is, in the present example, the length Lc of the contact region 15 in the Y axis direction may be shorter than the length Le of the emitter region 12 in the Y axis direction.

The injection suppression region 19 is provided in the main region 72 of the transistor portion 70. The injection suppression region 19 may be provided in the boundary region 74 of the transistor portion 70, and may be provided in both the main region 72 and the boundary region 74 of the transistor portion 70. By providing the injection suppression region 19 in at least the boundary region 74, hole injection during diode operation of the semiconductor device 100 can be suppressed, and reverse recovery loss Err can be reduced. In addition, by providing the injection suppression region 19 in both the main region 72 and the boundary region 74, hole injection during diode operation of the semiconductor device 100 can be more reliably suppressed, and reverse recovery loss Err can be reduced. The hole injection suppression by having the injection suppression region 19 will be described below in detail.

The injection suppression region 19 in the present example is provided at the front surface 21 of the mesa portion 71. The injection suppression region 19 may be provided extending from one trench portion to another adjacent trench portion in the array direction of the plurality of trench portions. The injection suppression region 19 in the present example is provided extending in the X axis direction from one of two trench portions sandwiching the mesa portion 71 to the other. The injection suppression region 19 may be or may not be in contact with the gate trench portion 40 or the dummy trench portion 30. The injection suppression region 19 in the present example is in contact with the dummy trench portion 30 and the gate trench portion 40. The injection suppression region 19 is also provided below the contact hole 54.

A length Li of the injection suppression region 19 in the extending direction of the plurality of trench portions may be 0.2 μm or more, or may be shorter than the length Le of the emitter region 12 in the extending direction of the plurality of trench portions. In the present example, the length Li of the injection suppression region 19 in the Y axis direction may be 0.2 μm or more, or may be shorter than the length Le of the emitter region 12 in the Y axis direction. The length Li of the injection suppression region 19 in the Y axis direction may be the length Le of the emitter region 12 in the Y axis direction or less, half or less of the length Le of the emitter region 12 in the Y axis direction, or one-third or less of the length Le of the emitter region 12 in the Y axis direction. The injection suppression region 19 may not be in contact with the emitter region 12 at the front surface 21 of the semiconductor substrate 10.

The anode region 13 is a region of the second conductivity type.

The anode region 13 in the present example is of the P− type as an example. The anode region 13 in the present example is provided at the front surface 21 of the mesa portion 81. The anode region 13 is also provided below the contact hole 54.

FIG. 1B illustrates an example of a cross section a-a′ in FIG. 1A. The cross section a-a′ is an XZ plane which passes through the emitter region 12 in the transistor portion 70. In the cross section a-a′, the semiconductor device 100 in the present example has the semiconductor substrate 10, the interlayer dielectric film 38, the emitter electrode 52, and a collector electrode 24. The drift region 18 is a region of the first conductivity type which is provided in the

semiconductor substrate 10. The drift region 18 in the present example is of the N− type as an example. The drift region 18 may be a region which has remained without other doping regions formed in the semiconductor substrate 10. That is, a doping concentration in the drift region 18 may be a doping concentration in the semiconductor substrate 10.

A buffer region 20 is a region of the first conductivity type which is provided at the back surface 23 side of the semiconductor substrate 10 relative to the drift region 18. The buffer region 20 in the present example is of the N type as an example. A doping concentration of the buffer region 20 may be higher than the doping concentration of the drift region 18. The buffer region 20 may function as a field stop layer which prevents a depletion layer extending from a lower surface side of the base region 14 from reaching the collector region 22 of the second conductivity type. It is to be noted that the buffer region 20 may be omitted.

The collector region 22 is provided below the buffer region 20 in the transistor portion 70. The collector region 22 has the second conductivity type. The collector region 22 in the present example is of the P+ type as an example.

The cathode region 82 is provided below the buffer region 20 in the diode portion 80. The cathode region 82 has the first conductivity type. The cathode region 82 in the present example is of the N+ type as an example. A boundary between the collector region 22 and the cathode region 82 is a boundary between the transistor portion 70 and the diode portion 80.

The collector electrode 24 is formed at the back surface 23 of the semiconductor substrate 10. The collector electrode 24 is formed of a conductive material such as metal. At least a partial region of the collector electrode 24 may be formed of a metal such as aluminum (Al) or copper (Cu), or a metal alloy such as aluminum-silicon alloy (AlSi) or aluminum-silicon-copper alloy (AlSiCu). The collector electrode 24 may have a barrier metal formed by titanium, titanium alloy or the like at the semiconductor substrate 10 side or outer side relative to the region formed by aluminum or the like.

The base region 14 is a region of the second conductivity type provided above the drift region 18. The base region 14 is of the P− type as an example. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in contact with the gate trench portion 40. The emitter region 12 may be or may not be in contact with the dummy trench portion 30.

The anode region 13 is provided above the drift region 18. A doping concentration of the anode region 13 may be the same as or may be different from a doping concentration of the base region 14. As an example, the doping concentration of the anode region 13 is lower than the doping concentration of the base region 14. The anode region 13 may be formed by the same process as the base region 14, or may be formed by a different process.

An accumulation region 16 is provided in contact with the gate trench portion 40. The accumulation region 16 may or may not be in contact with the dummy trench portion 30. The accumulation region 16 is of the N+ type as an example. A doping concentration of the accumulation region 16 may be higher than the doping concentration of the drift region 18. An ion implantation dose amount of the accumulation region 16 may be 1.0E+12 cm⁻² or more and 3.0E+13 cm⁻² or less. Providing the accumulation region 16 can increase a carrier injection enhancement effect (IE effect) to reduce an on-voltage of the transistor portion 70.

One or more gate trench portions 40 and one or more dummy trench portions 30 are provided at the front surface 21. Each trench portion is provided from the front surface 21 to the drift region 18. In a region provided with at least any of the emitter region 12, the anode region 13, the base region 14, the contact region 15, or the accumulation region 16, each trench portion also penetrates these regions to reach the drift region 18. The configuration in which the trench portion penetrates each region is not limited to the one manufactured in an order of formation of the trench portion after formation of each region. A case where each region is formed between the trench portions after formation of the trench portions is also included as a case where the trench portion penetrates each region.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor at the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 at the front surface 21.

The gate conductive portion 44 includes a region opposing the adjacent base region 14 at the side of the mesa portion 71 by sandwiching the gate dielectric film 42 in a depth direction of the semiconductor substrate 10. When a predetermined voltage is applied to the gate conductive portion 44, a channel is formed by an electron inversion layer in a surface layer of the base region 14 at an interface in contact with the gate trench.

The dummy trench portion 30 may have the same structure as that of the gate trench portion 40. The dummy trench portion 30 has a dummy trench, a dummy dielectric film 32, and a dummy conductive portion 34 which are formed at the front surface 21 side. The dummy dielectric film 32 is formed covering the inner wall of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 may be covered with the interlayer dielectric film 38 at the front surface 21.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. A film thickness of the interlayer dielectric film 38 is, for example, 1.0 μm, but is not limited to this.

The interlayer dielectric film 38 may be a silicon oxide film. The interlayer dielectric film 38 may be a BPSG (Boro-phospho Silicate Glass) film, may be a BSG (borosilicate glass) film, or may be a PSG (Phosphosilicate glass) film. The interlayer dielectric film 38 may also include a high temperature silicon oxide (HTO: High Temperature Oxide) film.

The emitter electrode 52 is provided above the semiconductor substrate 10 with the interlayer dielectric film 38 interpolated between them. The emitter electrode 52 may have a main metal portion 520, a barrier metal 522, and a plug layer 524.

The main metal portion 520 may be formed of a metal such as aluminum (Al) or copper (Cu), or a metal alloy such as aluminum-silicon alloy (AlSi) or aluminum-silicon-copper alloy (AlSiCu). Material of the main metal portion 520 may be the same as or different from the material of the collector electrode 24.

The barrier metal 522 may be provided in contact with the front surface 21 of the semiconductor substrate 10. In either case where the injection suppression region 19 is of the P type or the N type, material of the barrier metal 522 may include at least one of titanium, titanium nitride, tungsten, tungsten titanium, or tantalum. When the injection suppression region 19 is of the P type, the material of the barrier metal 522 may be material including at least one metal element which may be cobalt (Co), nickel (Ni), magnesium (Mg), vanadium (V), lanthanum (La), palladium (Pd), or zirconium (Zr).

The plug layer 524 may be provided in contact with an inner side of the barrier metal 522. Material of the plug layer 524 may be a plug metal such as tungsten or copper.

A back surface side lifetime control region 151 may be provided in both the transistor portion 70 and the diode portion 80. It is to be noted that the back surface side lifetime control region 151 may be omitted. The back surface side lifetime control region 151 is a region where a lifetime killer has intentionally been formed by injecting an impurity inside the semiconductor substrate 10, or the like. As an example, the back surface side lifetime control region 151 is formed by injecting helium into the semiconductor substrate 10. The back surface side lifetime control region 151 may also be formed by injecting protons. By providing the back surface side lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements configuring the semiconductor substrate 10, or dislocation. In addition, the lifetime killer may be a noble gas element such as helium and neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements configuring the semiconductor substrate 10, or may be a dislocation concentration. In addition, the lifetime killer concentration may be a chemical concentration of the noble gas element such as helium and neon, or may be a chemical concentration of the metal element such as platinum.

The back surface side lifetime control region 151 is provided at the back surface 23 side relative to a center Pc of the drift region 18 in the depth direction of the semiconductor substrate 10. The back surface side lifetime control region 151 in the present example is provided in the buffer region 20. The back surface side lifetime control region 151 in the present example is provided on an entire surface of the semiconductor substrate 10 in the XY plane, and can be formed without using a mask. The back surface side lifetime control region 151 may be provided in a part of the semiconductor substrate 10 in the XY plane. An impurity dose amount for forming the back surface side lifetime control region 151 may be 0.5 E+10 cm⁻² or more and 1.0 E+14 cm⁻² or less, or may be 5.0 E+10 cm⁻² or more and 1.0 E+13 cm⁻² or less.

The back surface side lifetime control region 151 may be formed by an injection from the back surface 23 side. Accordingly, it becomes easy to avoid an effect at the front surface 21 side of the semiconductor device 100. For example, the back surface side lifetime control region 151 is formed by irradiating it with helium or protons from the back surface 23 side. Herein, which of the front surface 21 side and the back surface 23 side the injection is performed from for forming the back surface side lifetime control region 151 can be determined by acquiring a state of the front surface 21 side by an SRP method or a measurement of a leakage current.

A front surface side lifetime control region 152 is provided at the front surface 21 side relative to the center Pc of the drift region 18 in the depth direction of the semiconductor substrate 10. The front surface side lifetime control region 152 in the present example is provided in the drift region 18. The front surface side lifetime control region 152 may be provided in both the transistor portion 70 and the diode portion 80. The front surface side lifetime control region 152 may be provided in at least a part of the diode portion 80, and may not be provided in at least a part of the transistor portion 70. The front surface side lifetime control region 152 may be provided extending from the diode portion 80 to at least a part of the boundary region 74 of the transistor portion 70, and may be provided extending from the diode portion 80 beyond the boundary region 74 of the transistor portion 70 to the main region 72 of the transistor portion 70. In another example, the front surface side lifetime control region 152 may be provided in at least a part of the transistor portion 70, and may not be provided in at least a part of the diode portion 80. The front surface side lifetime control region 152 can suppress hole injection from the anode region 13 of the diode portion 80 and/or the contact region 15 of the transistor portion 70, and reduce reverse recovery loss Err.

The front surface side lifetime control region 152 may be formed by any of the methods for forming the back surface side lifetime control region 151. The element, the dose amount, or the like for forming the back surface side lifetime control region 151 may be the same as or different from those for forming the front surface side lifetime control region 152.

The front surface side lifetime control region 152 may be formed by an irradiation from the front surface 21 of the semiconductor substrate 10. The front surface side lifetime control region 152 may be formed by an irradiation from the back surface 23 side of the semiconductor substrate 10. The front surface side lifetime control region 152 in the present example is provided below the gate trench portion 40. When a particle beam or the like for forming the front surface side lifetime control region 152 passes through a MOS gate structure of the semiconductor device 100, defects may occur at an interface between the gate dielectric film 42 and the semiconductor substrate. In the present invention, since the dose amount for forming the front surface side lifetime control region 152 can be reduced by providing the injection suppression region 19, there is an effect that reduces influence of defects at the interface.

The semiconductor device 100 may be a power semiconductor device for performing power control and the like. The semiconductor device 100 in the present example may have a vertical semiconductor structure in which a back surface side metal layer is provided at the back surface 23 side of the semiconductor substrate 10. It is to be noted that the semiconductor device 100 may have a horizontal semiconductor structure in which the metal layer is not provided at the back surface 23 side.

It is to be noted that in the present example, an RC-IGBT having a trench gate structure is described as an example of the semiconductor device 100. It is to be noted that the semiconductor device 100 may be a semiconductor device having a planar gate structure. The semiconductor device 100 may include an N-channel MOSFET or P-channel MOSFET.

FIG. 1C illustrates an example of a cross section b-b′ in FIG. 1A. The cross section b-b′ is a YZ plane which passes through the contact hole 54 in the transistor portion 70. The injection suppression region 19 in the present example has a region of the second conductivity type. The injection suppression region 19 is of the P− type as an example. The contact region 15 is provided above the base region 14. A depth position of a lower surface of the contact region 15 may be the same as or deeper than a depth position of the emitter region 12. The contact region 15 may be formed to extend around a lower surface side of the emitter region 12.

The base region 14 may not be in contact with the emitter electrode 52. That is, the emitter region 12 or the injection suppression region 19 may be provided between adjacent contact regions 15 in the extending direction of the plurality of trench portions. It is to be noted that the base region 14 may be in contact with the emitter electrode 52.

The injection suppression region 19 may be in contact with the lower surface of the contact region 15. The injection suppression region 19 may be in contact with a side surface of the contact region 15. It is to be noted that the injection suppression region 19 may not be in contact with the lower surface or the side surface of the contact region 15.

The injection suppression region 19 may have the base region 14. That is, a doping concentration of the injection suppression region 19 may be the same as the doping concentration of the base region 14, and the injection suppression region 19 may be formed by the same process as the base region 14. In this case, the base region 14 may be in contact with the emitter electrode 52. The doping concentration of the injection suppression region 19 is lower than the doping concentration of the contact region 15.

The doping concentration of the injection suppression region 19 may be lower than the doping concentration of the base region 14. When the doping concentration of the anode region 13 of the diode portion 80 is lower than the doping concentration of the base region 14, the doping concentration of the injection suppression region 19 may be the same as the doping concentration of the anode region 13. That is, the injection suppression region 19 may be formed by the same process as the anode region 13. The doping concentration of the injection suppression region 19 is lower than the doping concentration of the contact region 15.

When the semiconductor device 100 operates as a diode, a body diode between the cathode region 82 of the diode portion 80 and the contact region 15 of the transistor portion 70 operates. When an electron current from the cathode region 82 of the diode portion 80 reaches the contact region 15, holes are injected from the contact region 15, and reverse recovery loss Err increases. The semiconductor device 100 in the present example can suppress hole injection from the transistor portion 70 to the diode portion 80 and reduce reverse recovery loss Err by being provided with the injection suppression region 19 of the second conductivity type having a doping concentration which is lower than that of the contact region 15, and making a surface of the transistor portion 70 have a low concentration.

The semiconductor device 100 in the present example has reduced width of the contact region 15 and is provided with the injection suppression region 19. Accordingly, since the surface of the transistor portion 70 can be made to have a lower concentration, reverse recovery loss Err can be reduced compared to when the width of the contact region 15 is simply reduced.

The semiconductor device 100 in the present example includes the front surface side lifetime control region 152 provided below the injection suppression region 19. Accordingly, hole injection from the transistor portion 70 can be suppressed, and reverse recovery loss Err can be further reduced. It is to be noted that the front surface side lifetime control region 152 may be omitted.

FIG. 1D illustrates the cross section b-b′ of a modification example of the semiconductor device 100. The injection suppression region 19 in the present example is different from the embodiment in FIG. 1C in that it has a region of the first conductivity type. The injection suppression region 19 is of the N− type as an example. The present example describes points that differ from the embodiment in FIG. 1C in particular, and other points may be the same as those of the embodiment in FIG. 1C.

The injection suppression region 19 may have the drift region 18. That is, the doping concentration of the injection suppression region 19 may be the same as the doping concentration of the drift region 18, and the injection suppression region 19 may be formed by the same process as the drift region 18.

The doping concentration of the injection suppression region 19 may be 5E16 cm⁻³ or less. The doping concentration of the injection suppression region 19 may be the same as or higher than the doping concentration of the drift region 18. The doping concentration of the injection suppression region 19 may be lower than the doping concentration of the emitter region 12. The doping concentration of the injection suppression region 19 may be the same as or lower than the doping concentration of the accumulation region 16. The doping concentration of the injection suppression region 19 may be a concentration at which a Schottky junction can be formed with the emitter electrode 52.

The injection suppression region 19 may form a Schottky junction with the emitter electrode 52. The Schottky junction is a metal-semiconductor junction that occurs when a work function of a metal is greater than a work function of a semiconductor. That is, the work function of a semiconductor which is material of the injection suppression region 19 may be less than the work function of a metal which is material of the emitter electrode 52. As an example, the injection suppression region 19 may form the Schottky junction with the barrier metal 522 having the emitter electrode 52, and the work function of the semiconductor which is the material for the injection suppression region 19 may be less than the work function of the metal which is the material of the barrier metal 522.

Even if the work function of the metal is greater than the work function of the semiconductor, when the doping concentration of the semiconductor is high, a tunnel effect occurs due to narrowing of the depletion layer, and ostensibly, an ohmic junction may be formed instead of the Schottky junction. The doping concentration of the injection suppression region 19 may be a concentration at which the Schottky junction can be formed with the emitter electrode 52.

On the other hand, the emitter region 12 and the contact region 15 may not form the Schottky junction with the emitter electrode 52. That is, the doping concentrations of the emitter region 12 and the contact region 15 may be high enough to ostensibly form the ohmic junction instead of the Schottky junction with the emitter electrode 52.

When the injection suppression region 19 forms the Schottky junction with the emitter electrode 52, a current path which passes through the emitter electrode 52, the injection suppression region 19, the cathode region 82 of the diode portion 80, and the collector electrode 24 can be formed. Accordingly, during diode operation of the semiconductor device 100, since an electron current from the cathode region 82 of the diode portion 80 is extracted by the emitter electrode 52 without reaching the contact region 15, hole injection to the diode portion 80 from the transistor portion 70 can be suppressed, and reverse recovery loss Err can be reduced.

The semiconductor device 100 in the present example has reduced width of the contact region 15 and is provided with the injection suppression region 19. Accordingly, since a path of the electron current from the cathode region 82 of the diode portion 80 can be secured, reverse recovery loss Err can be reduced compared to when the width of the contact region 15 is simply reduced.

In addition, in the semiconductor device 100 in the present example, the emitter region 12, the contact region 15, and the injection suppression region 19 are arrayed in the extending direction of the plurality of trench portions. Accordingly, compared to when they are arrayed in the array direction of the plurality of trench portions, the injection suppression region 19 can be made wide regardless of the array interval of the plurality of trench portions. That is, although there is a risk that the path of the electron current from the cathode region 82 of the diode portion 80 cannot be sufficiently secured and reverse recovery loss Err cannot be reduced when the injection suppression region 19 is narrow, by making the injection suppression region 19 wide regardless of the array interval of the plurality of trench portions, the reverse recovery loss Err can be reduced.

The semiconductor device 100 in the present example includes the front surface side lifetime control region 152 provided below the injection suppression region 19. Accordingly, hole injection from the transistor portion 70 can be suppressed, and reverse recovery loss Err can be further reduced. It is to be noted that the front surface side lifetime control region 152 may be omitted.

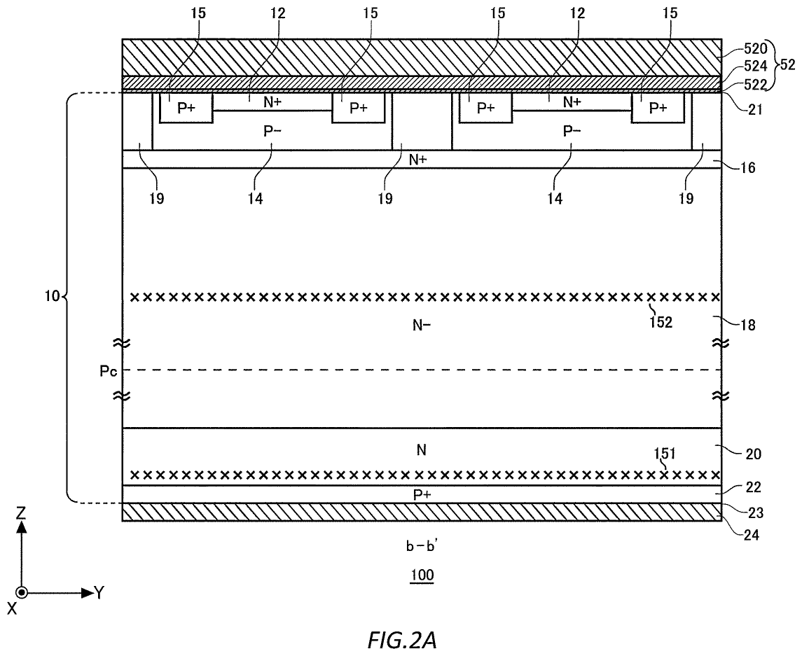

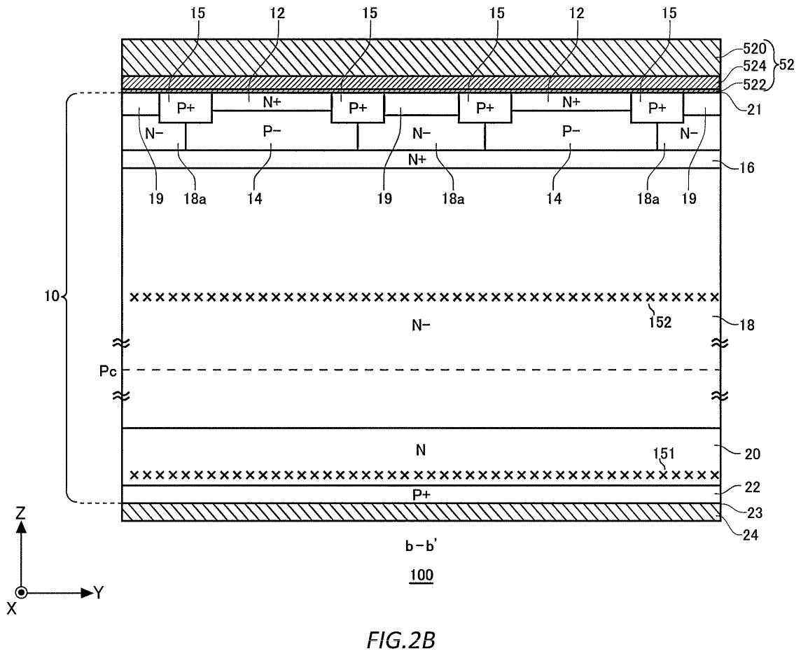

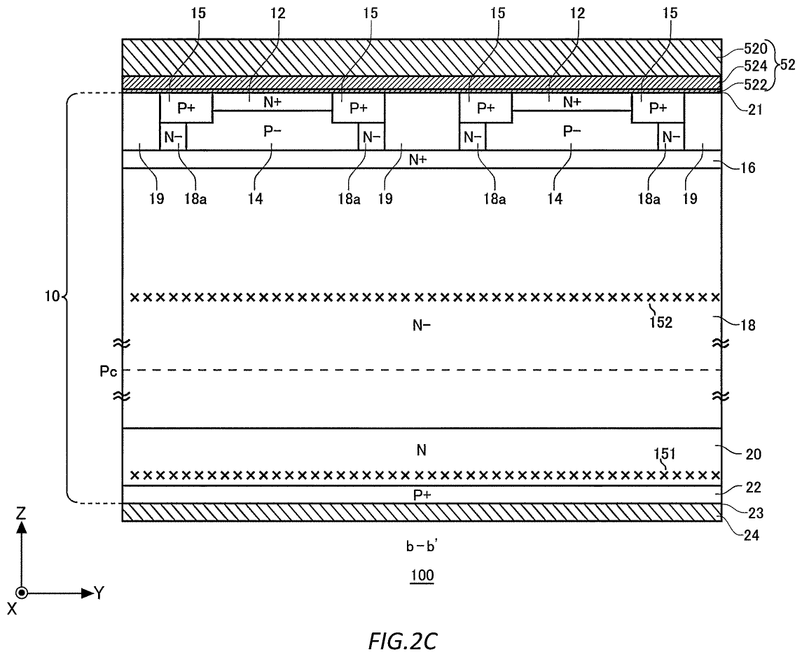

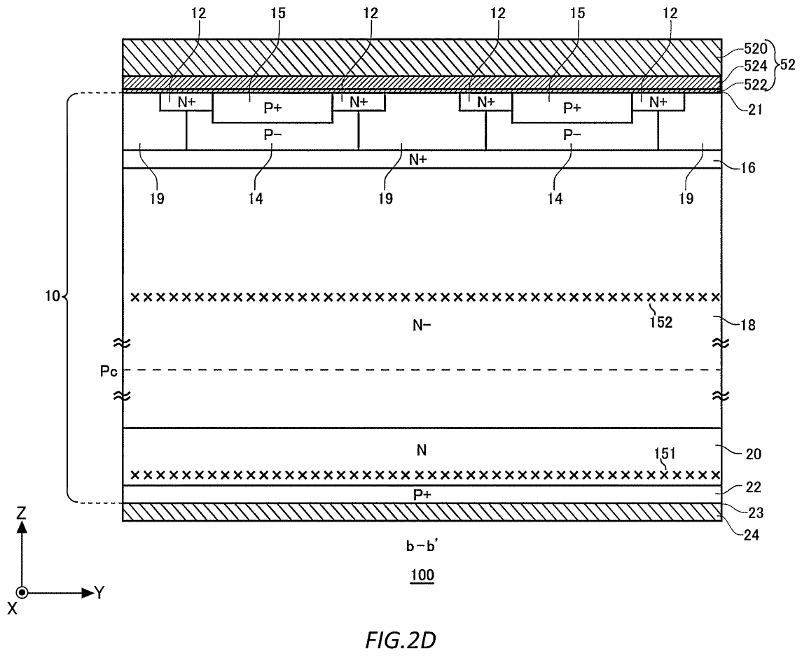

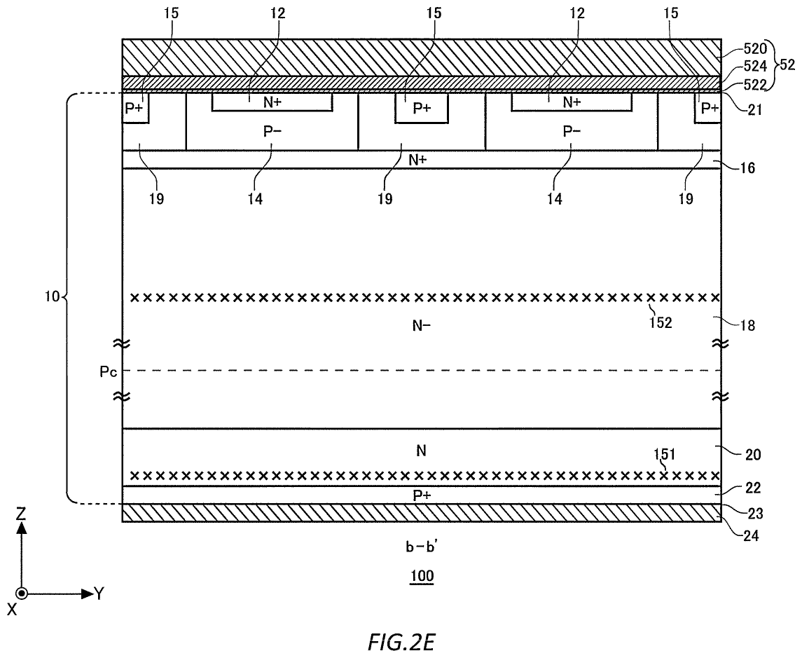

FIG. 2A illustrates the cross section b-b′ of a modification example of the semiconductor device 100. The semiconductor device 100 in the present example differs from the embodiments in FIG. 1C and FIG. 1D in that the base region 14 is in contact with the emitter electrode 52. The injection suppression region 19 in the present example may have a region of the first conductivity type or the second conductivity type. The present example describes points that differ from the embodiments in FIG. 1C and FIG. 1D in particular, and other points may be the same as those of the embodiments in FIG. 1C and/or FIG. 1D. In the semiconductor device 100 in the present example, the injection suppression region 19, the base region 14, the contact region 15, the emitter region 12, the contact region 15, and the base region 14 are provided repeatedly in this order in the extending direction of the plurality of trench portions at the front surface 21 of the semiconductor substrate 10.

FIG. 2B illustrates the cross section b-b′ of a modification example of the semiconductor device 100. The semiconductor device 100 in the present example differs from the embodiments in FIG. 1C and FIG. 1D in that a lower surface of the injection suppression region 19 is provided at the front surface 21 side of the semiconductor substrate 10 relative to the lower surface of the base region 14 in the depth direction of the semiconductor substrate 10. The injection suppression region 19 in the present example may have a region of the first conductivity type or the second conductivity type. The present example describes points that differ from the embodiments in FIG. 1C and FIG. 1D in particular, and other points may be the same as those of the embodiments in FIG. 1C and/or FIG. 1D.

The semiconductor device 100 may include a drift region 18a in a region from a depth position of the lower surface of the base region 14 to a depth position of the lower surface of the injection suppression region 19 in the depth direction of the semiconductor substrate 10 in which the base region 14 is not provided. The depth position of the lower surface of the injection suppression region 19 may be shallower than the depth position of the lower surface of the emitter region 12 or the depth position of the lower surface of the contact region 15, or deeper than the depth position of the lower surface of the contact region 15. The drift region 18a may be substituted by the base region 14.

FIG. 2C illustrates the b-b′ cross section of a modification example of the semiconductor device 100. The semiconductor device 100 in the present example differs from the embodiments in FIG. 1C and FIG. 1D in that the injection suppression region 19 is not in contact with the base region 14 at the lower surface side of the contact region 15. The injection suppression region 19 in the present example may have a region of the first conductivity type or the second conductivity type. The present example describes points that differ from the embodiments in FIG. 1C and FIG. 1D in particular, and other points may be the same as those of the embodiments in FIG. 1C and/or FIG. 1D.

The semiconductor device 100 may include the drift region 18a in a region from the depth position of the lower surface of the base region 14 to the depth position of the lower surface of the contact region 15 in the depth direction of the semiconductor substrate 10 in which the base region 14 and the injection suppression region 19 are not provided.

FIG. 2D illustrates the cross section b-b′ of a modification example of the semiconductor device 100. The semiconductor device 100 in the present example differs from the embodiments in FIG. 1C and FIG. 1D in that the injection suppression region 19 is provided between the emitter regions 12. The injection suppression region 19 in the present example may have a region of the first conductivity type or the second conductivity type. The present example describes points that differ from the embodiments in FIG. 1C and FIG. 1D in particular, and other points may be the same as those of the embodiments in FIG. 1C and/or FIG. 1D. In the semiconductor device 100 in the present example, the injection suppression region 19, the emitter region 12, the contact region 15, and the emitter region 12 are provided repeatedly in this order in the extending direction of the plurality of trench portions at the front surface 21 of the semiconductor substrate 10.

In the depth direction of the semiconductor substrate 10, the depth position of the lower surface of the injection suppression region 19 may be the same as or shallower than the depth position of the lower surface of the base region 14. The injection suppression region 19 may or may not be in contact with the base region 14 at the lower surface side of the emitter region 12. At the front surface 21 of the semiconductor substrate 10, the base region 14 or the drift region 18a may be exposed between the injection suppression region 19 and the emitter region 12.

FIG. 2E illustrates the cross section b-b′ of a modification example of the semiconductor device 100. The semiconductor device 100 in the present example differs from the embodiments in FIG. 1C and FIG. 1D in that the injection suppression region 19 is provided between the emitter region 12 and the contact region 15. The injection suppression region 19 in the present example may have a region of the first conductivity type or the second conductivity type. The present example describes points that differ from the embodiments in FIG. 1C and FIG. 1D in particular, and other points may be the same as those of the embodiments in FIG. 1C and/or FIG. 1D. In the semiconductor device 100 in the present example, the injection suppression region 19, the emitter region 12, the injection suppression region 19, and the contact region 15 are provided repeatedly in this order in the extending direction of the plurality of trench portions at the front surface 21 of the semiconductor substrate 10. The injection suppression region 19 may not be provided on both sides of the emitter region 12 and the contact region 15, and may be provided on one side.

In the depth direction of the semiconductor substrate 10, the depth position of the lower surface of the injection suppression region 19 may be the same as or shallower than the depth position of the lower surface of the base region 14. The injection suppression region 19 may or may not be in contact with the base region 14 at the lower surface side of the emitter region 12. At the front surface 21 of the semiconductor substrate 10, the base region 14 or the drift region 18a may be exposed between the injection suppression region 19 and the emitter region 12 or the contact region 15.

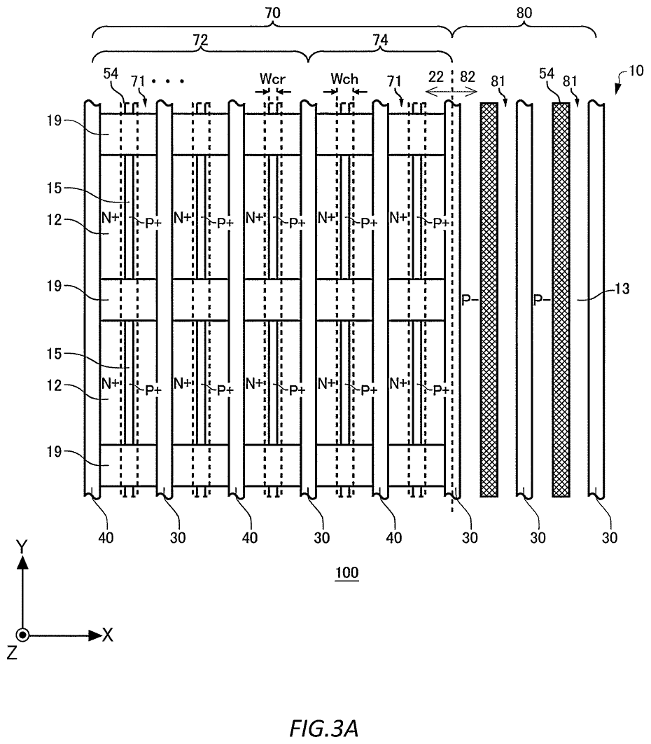

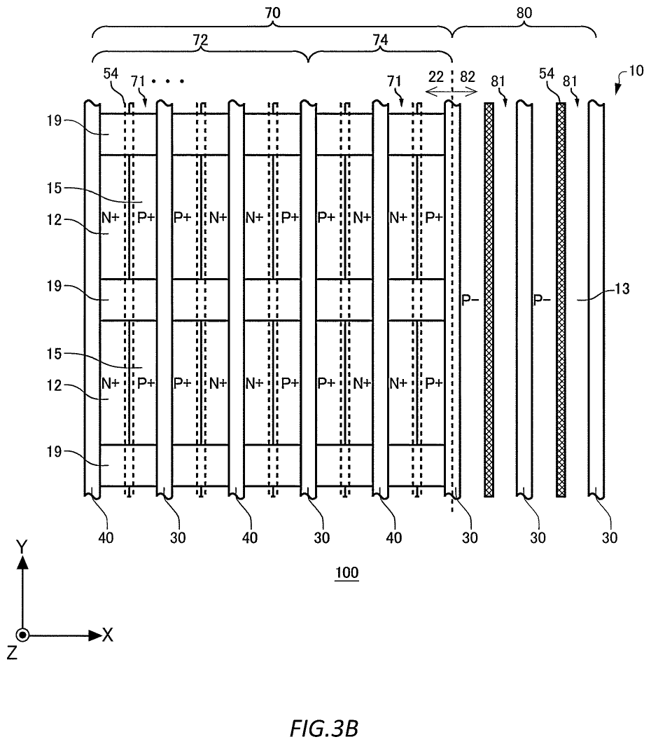

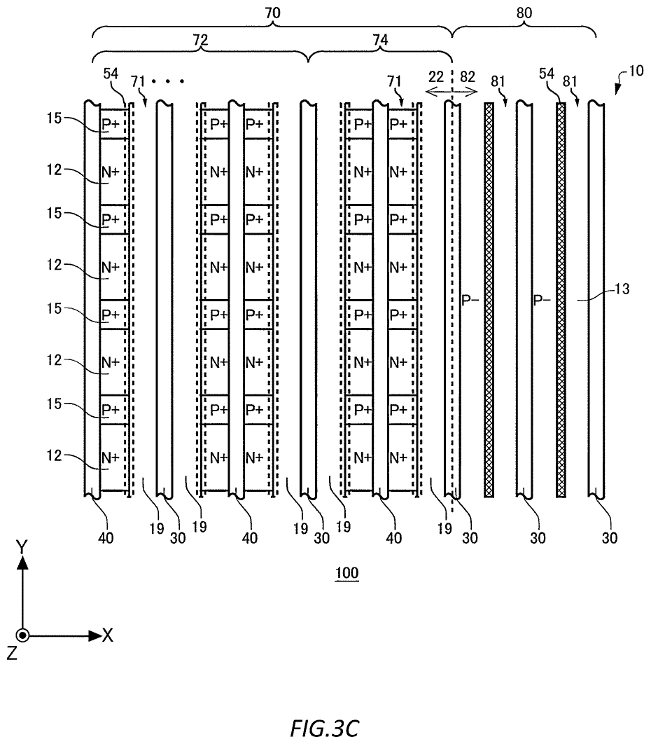

FIG. 3A illustrates an example of a top view of a modification example of the semiconductor device 100. In the present drawing, for the sake of explanation, the contact hole 54 in the transistor portion 70 is illustrated as a dotted line. The semiconductor device 100 in the present example differs from the embodiment in FIG. 1A in that the emitter region 12 and the contact region 15 are provided extending in the extending direction of the plurality of trench portions. The present example describes points that differ from the embodiment in FIG. 1A in particular, and other points may be the same as those of the embodiment in FIG. 1A.

The emitter region 12 and the contact region 15 may be in direct contact with one another in the array direction of the plurality of trench portions. The injection suppression region 19 may be provided extending from one trench portion to another adjacent trench portion in the array direction of the plurality of trench portions. That is, in the semiconductor device 100 in the present example, at the front surface 21 of the semiconductor substrate 10, a region in which the injection suppression region 19 is provided extending from one trench portion to another adjacent trench portion in the array direction of the plurality of trench portions and a region in which the emitter region 12 and the contact region 15 are provided in direct contact with one another in the array direction of the plurality of trench portions and extending in the extending direction of the plurality of trench portions are provided alternately in the extending direction of the plurality of trench portions.

The emitter region 12 may be in contact with the gate trench portion 40 and the dummy trench portion 30. The contact region 15 may not be in contact with the gate trench portion 40 and the dummy trench portion 30. That is, the emitter region 12 and the contact region 15 may be provided from one trench portion to another adjacent trench portion in a stripe pattern in an order of the emitter region 12, the contact region 15, and the emitter region 12 in the array direction of the plurality of trench portions.

A width Wcr of the contact region 15 in the array direction of the plurality of trench portions may be less than a width Wch of the contact hole 54 in the array direction of the plurality of trench portions. The contact region 15 may be provided on an inner side of the contact hole 54, and the contact hole 54 may be provided above the contact region 15 and the emitter region 12. That is, the emitter region 12 and the contact region 15 may be electrically connected to the emitter electrode 52 via the contact hole 54.

FIG. 3B illustrates an example of a top view of a modification example of the semiconductor device 100. In the present drawing, for the sake of explanation, the contact hole 54 in the transistor portion 70 is illustrated as a dotted line. The semiconductor device 100 in the present example differs from the embodiment in FIG. 3A in that the contact region 15 is provided in contact with the dummy trench portion 30. The present example describes points that differ from the example in FIG. 3A in particular, and other points may be the same as those of the example in FIG. 3A.

The emitter region 12 and the contact region 15 may be arranged in the array direction of the plurality of trench portions or may be provided extending in the extending direction of the plurality of trench portions in the mesa portion 71 between the gate trench portion 40 and the dummy trench portion 30. The emitter region 12 may be provided in contact with the gate trench portion 40 in the mesa portion 71 between the gate trench portion 40 and the dummy trench portion 30. The contact region 15 may be provided in contact with the dummy trench portion 30 in the mesa portion 71 between the gate trench portion 40 and the dummy trench portion 30. The injection suppression region 19 may be provided extending from one trench portion

to another adjacent trench portion in the array direction of the plurality of trench portions. That is, in the semiconductor device 100 in the present example, at the front surface 21 of the semiconductor substrate 10, a region in which the injection suppression region 19 is provided extending from one trench portion to another adjacent trench portion in the array direction of the plurality of trench portions and a region in which the emitter region 12 and the contact region 15 are arranged in the array direction of the plurality of trench portions and provided extending in the extending direction of the plurality of trench portions are provided alternately in the extending direction of the plurality of trench portions.

A boundary between the emitter region 12 and the contact region 15 may be provided below the contact hole 54, and the contact hole 54 may be provided above the emitter region 12 and the contact region 15. That is, the emitter region 12 and the contact region 15 may be electrically connected to the emitter electrode 52 via the contact hole 54.

FIG. 3C illustrates an example of a top view of a modification example of the semiconductor device 100. In the present drawing, for the sake of explanation, the contact hole 54 in the transistor portion 70 is illustrated as a dotted line. The semiconductor device 100 in the present example differs from the embodiment in FIG. 1A in that the injection suppression region 19 is provided extending in the extending direction of the plurality of trench portions. The present example describes points that differ from the embodiment in FIG. 1A in particular, and other points may be the same as those of the embodiment in FIG. 1A.

The injection suppression region 19 may be provided in contact with the dummy trench portion 30 in the mesa portion 71 between the gate trench portion 40 and the dummy trench portion 30. The injection suppression region 19 may not be in contact with the gate trench portion 40.

The emitter region 12 and the contact region 15 may be provided alternately in the extending direction of the plurality of trench portions. The emitter region 12 and the contact region 15 may be provided in contact with the gate trench portion 40 in the mesa portion 71 between the gate trench portion 40 and the dummy trench portion 30. The injection suppression region 19 may be in contact with the emitter region 12 and the contact region 15 in the array direction of the plurality of trench portions.

In the semiconductor device 100 in the present example, in the mesa portion 71 between the gate trench portion 40 and the dummy trench portion 30, a region in which the injection suppression region 19 is provided extending in the extending direction of the plurality of trench portions and a region in which the emitter region 12 and the contact region 15 are provided alternately in the extending direction of the plurality of trench portions are arranged in the array direction of the plurality of trench portions. A boundary between the injection suppression region 19, and emitter region 12 and the contact region 15 may be provided below the contact hole 54, and the contact hole 54 may be provided above the emitter region 12, the contact region 15, and the injection suppression region 19. That is, the emitter region 12, the contact region 15, and the injection suppression region 19 may be electrically connected to the emitter electrode 52 via the contact hole 54.

While the present invention has been described by way of the embodiments, the technical scope of the present invention is not limited to the above-described embodiments. It is apparent to persons skilled in the art that various alterations or improvements can be made to the above described embodiments. It is also apparent from the described scope of the claims that the embodiments added with such alterations or improvements can be included the technical scope of the present invention. For example, the injection suppression region 19 may have both a region of the first conductivity type and a region of the second conductivity type.

Note that the operations, procedures, steps, and stages of each process performed by an apparatus, system, program, and method shown in the claims, specification, or drawings can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10: semiconductor substrate; 12 emitter region; 13 anode region; 14 base region; 15 contact region; 16 accumulation region; 18 drift region; 19 injection suppression region; 20 buffer region; 21 front surface; 22 collector region; 23 back surface; 24 collector electrode; 30 dummy trench portion; 32 dummy dielectric film; 34 dummy conductive portion; 38 interlayer dielectric film; 40 gate trench portion; 42 gate dielectric film; 44 gate conductive portion; 52 emitter electrode; 54 contact hole; 70 transistor portion; 71 mesa portion; 72 main region; 74 boundary region; 80 diode portion; 81 mesa portion; 82 cathode region; 100 semiconductor device; 151 back surface side lifetime control region; 152 front surface side lifetime control region; 520 main metal portion; 522 barrier metal; 524 plug layer.

What is claimed is:

1. A semiconductor device comprising a transistor portion and a diode portion, the semiconductor device comprising:
a plurality of trench portions provided at a front surface of a semiconductor substrate;
a drift region of a first conductivity type provided in the semiconductor substrate;
a base region of a second conductivity type provided above the drift region;
an emitter region of the first conductivity type provided above the base region and having a doping concentration higher than that of the drift region;
a contact region of the second conductivity type provided above the base region and having a doping concentration higher than that of the base region;
an injection suppression region provided at the front surface of the semiconductor substrate; and
an emitter electrode provided above the semiconductor substrate, wherein
the transistor portion has a main region for performing transistor operation, and
the injection suppression region is provided in the main region of the transistor portion.

2. The semiconductor device according to claim 1, wherein
the injection suppression region has a region of the second conductivity type.

3. The semiconductor device according to claim 2, wherein
the injection suppression region has the base region.

4. The semiconductor device according to claim 2, wherein
a doping concentration of the injection suppression region is lower than a doping concentration of the base region.

5. The semiconductor device according to claim 1, wherein
the injection suppression region has a region of the first conductivity type and forms a Schottky junction with the emitter electrode.

6. The semiconductor device according to claim 1, wherein
the injection suppression region has a region of an N type, and
a doping concentration of the injection suppression region is 5E16 cm⁻³ or less.

7. The semiconductor device according to claim 1, wherein
the injection suppression region has a region of an N type, and
the emitter electrode is in contact with the front surface of the semiconductor substrate and has a barrier metal including at least one of titanium, titanium nitride, tungsten, tungsten titanium, or tantalum.

8. The semiconductor device according to claim 5, wherein
the injection suppression region has the drift region.

9. The semiconductor device according to claim 1, wherein
the base region is not in contact with the emitter electrode.

10. The semiconductor device according to claim 1, wherein
the injection suppression region is in contact with a lower surface of the contact region.

11. The semiconductor device according to claim 1, wherein
a length of the injection suppression region in an extending direction of the plurality of trench portions is 0.2 μm or more, and is shorter than a length of the emitter region in the extending direction of the plurality of trench portions.

12. The semiconductor device according to claim 1, wherein
the injection suppression region is provided extending from one trench portion to another adjacent trench portion in an array direction of the plurality of trench portions.

13. The semiconductor device according to claim 1, wherein
the injection suppression region is not in contact with the emitter region at the front surface of the semiconductor substrate.

14. The semiconductor device according to claim 1, wherein
the contact region is provided extending from one trench portion to another adjacent trench portion in an array direction of the plurality of trench portions.

15. The semiconductor device according to claim 1, wherein
a length of the contact region in an extending direction of the plurality of trench portions is shorter than a length of the emitter region in the extending direction of the plurality of trench portions.

16. The semiconductor device according to claim 1, wherein
a length of the emitter region in an extending direction of the plurality of trench portions is 0.1 μm or more and 3 μm or less.

17. The semiconductor device according to claim 1, wherein
the emitter region and the contact region are provided in direct contact with one another in an array direction of the plurality of trench portions and extending in an extending direction of the plurality of trench portions.

18. The semiconductor device according to claim 1, wherein
the plurality of trench portions have a gate trench portion and a dummy trench portion,
the emitter region and the contact region are arranged in an array direction of the plurality of trench portions and provided extending in an extending direction of the plurality of trench portions in a mesa portion between the gate trench portion and the dummy trench portion,
the emitter region is provided in contact with the gate trench portion in the mesa portion between the gate trench portion and the dummy trench portion, and
the contact region is provided in contact with the dummy trench portion in the mesa portion between the gate trench portion and the dummy trench portion.

19. The semiconductor device according to claim 1, wherein
the emitter region and the contact region are provided alternately in an extending direction of the plurality of trench portions, and
the injection suppression region is in contact with the emitter region and the contact region in an array direction of the plurality of trench portions and provided extending in the extending direction of the plurality of trench portions.

20. The semiconductor device according to claim 1, comprising
a lifetime control region provided on a front surface side of the semiconductor substrate relative to a center of the drift region in a depth direction of the semiconductor substrate and below the injection suppression region.
